(19) United States
(12) Patent Application Publication
(10) Pub. No.: US 2021/0167735 A1
(43) Pub. Date: Jun. 3, 2021

(54) DOHERTY POWER AMPLIFIERS WITH IMPROVED PEAKING AMPLIFIER MATCHING

(71) Applicant: NXP USA, Inc., AUSTIN, TX (US)

(72) Inventors: Faiza Baroudi, Villeneuve Tolosane (FR); Damien Scatamacchia, Toulouse (FR); Xavier Hue, FROUZINS (FR)

(21) Appl. No.: 16/740,417

(22) Filed: Jan. 11, 2020

(30) Foreign Application Priority Data
Dec. 2, 2019 (EP) 19306546.3

(51) Int. Cl. H03F 1/02; H03F 1/56; H03F 3/21; H03F 3/19

(52) U.S. Cl. CPC H03F 1/0288; H03F 1/56; H03F 2200/451; H03F 3/19; H03F 3/211

(57) ABSTRACT

The embodiments described herein can provide radio frequency (RF) amplifiers, and particularly Doherty power amplifiers. The Doherty amplifiers include a carrier amplifier, at least one peaking amplifier, and a combiner. In general, these Doherty amplifiers include an adaptive impedance transformation that provides a phase shift and modifies the impedance presented to one or more peaking amplifier(s) in the Doherty amplifier. Specifically, the combiner includes at least a first impedance transformer, second impedance transformer, and a third impedance transformer coupled between the first impedance transformer and the second impedance transformer. In accordance with the embodiments described herein, the third impedance transformer is configured to both provide both a phase shift and an impedance transformation.

### CROSS-REFERENCE TO RELATED APPLICATIONS

This application claims the priority under 35 U.S.C. § 119 of European patent application no. 19306546.3, filed Dec. 2, 2019 the contents of which are incorporated by reference herein.

### TECHNICAL FIELD

Embodiments of the subject matter described herein relate generally to amplifiers, and more particularly to radio frequency (RF) power amplifiers used in a variety of applications.

### BACKGROUND

In general, amplifiers are used to increase the power of signals. For example, in some applications amplifiers can be used to convert low-power radio frequency (RF) signals into larger RF signals for driving the antenna of a transmitter. In such cases, amplifiers may be implemented as part of an overall power amplifier used by an RF transmission system.

One reoccurring issue in RF amplifiers is efficiency. One type of high efficiency amplifier is a Doherty amplifier. In general, a Doherty amplifier divides an input RF signal and uses amplifiers of different classes to amplify the divided parts of the RF signal. Specifically, a Doherty amplifier typically uses a carrier amplifier and one or more peaking amplifiers, with the carrier amplifier used to amplify relatively low power input signals, and both the carrier amplifier and the one or more peaking amplifiers used to drive relatively high-power input signals (e.g., the peaks of the signal).

While such Doherty amplifiers can provide both relatively high power and relatively high efficiency over a large output power range, there is a continuing need for improvements in amplifier power and efficiency.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIGS. 1-3 are schematic diagrams of a Doherty amplifier in accordance with an example embodiment;

FIG. 4 is a schematic diagram of a Doherty amplifier in accordance with another example embodiment;

FIG. 5 is a schematic diagram of a Doherty amplifier in accordance with another example embodiment; and

FIG. 6 is a partial top view of a portion of a Doherty amplifier in accordance with example embodiments.

### DETAILED DESCRIPTION

The embodiments described herein can provide radio frequency (RF) amplifiers, and particularly Doherty power amplifiers, with improved performances. In general, this improved performances in Doherty power amplifiers are provided with an adaptive impedance transformation that modifies the impedance presented to one or more peaking amplifier(s) in the Doherty power amplifier. This modification of the impedance presented to the peaking amplifier(s) can be used to improve the performance of the Doherty power amplifier, including the peak power of the Doherty power amplifier.

Specifically, the Doherty amplifiers in the embodiments described herein include a carrier amplifier, at least one peaking amplifier, and a combiner. The combiner includes at least a first impedance transformer, second impedance transformer, and a third impedance transformer coupled between the first impedance transformer and the second impedance transformer. In accordance with the embodiments described herein, the third impedance transformer is configured to both provide an optimized phase shift and an optimized impedance.

In general, the optimized phase shift provided by the third impedance transformer presents an open impedance to the combining node between the first impedance transformer and the third impedance transformer during low power operation when the peaking amplifier is off. The optimized impedance provided by the third impedance transformer provides an optimal impedance at the node between the third impedance transformer and the second impedance transformer. The optimized impedance provided by the third impedance transformer changes impedance seen by the peaking amplifier(s) to improve the peaking amplifier and its performances. Specifically, the impedance change provided by the third impedance transformer can provide improved peaking amplifier adaptation. This can improve the overall efficiency and peak power of the Doherty amplifier, particularly during high power operation when the peaking amplifier is turned on (e.g., at back off). Thus, by providing both an optimized phase shift and optimized impedance the third impedance transformer can improve amplifier performance both when the peaking amplifier is off during low power operation and when the peaking amplifier is on during high power operation.

In one embodiment the Doherty amplifier is an asymmetric Doherty amplifier where the peaking amplifier has a significantly larger power capacity compared to the carrier amplifier. For example, the peaking amplifier can have a power capacity that is two or more times larger than the power capacity of the carrier amplifier. In such embodiments the change in impedance provided by the third impedance transformer can significantly improve the efficiency in the operation of the larger peaking amplifier. Specifically, the third impedance transformer can significantly improve the matching quality of the peaking amplifier when the peaking amplifier is turned on for large signal operation.

Conversely, the change in impedance provided by the third impedance transformer does not similarly change the impedance seen by the carrier amplifier and thus the output impedance seen by the carrier amplifier can independently configured to facilitate efficient operation of the carrier amplifier. Stated another way, the impedance transformation provided by the third impedance transformer facilitates a decoupling of the impedances provided at the carrier amplifier output and peaking amplifier output such that the optimal impedances can be provided to the outputs of both amplifiers to improve overall performance of the Doherty amplifier.

In general, a Doherty amplifier divides an input RF signal and uses amplifiers of different classes to amplify the divided parts of the RF signal. Specifically, a Doherty amplifier typically uses a carrier amplifier and one or more peaking amplifiers, with the carrier amplifier used to amplify relatively low power input signals, and both the carrier amplifier and the one or more peaking amplifiers used to drive relatively high power input signals (e.g., the peaks of the signal). In such an implementation, the carrier amplifier is typically biased to operate as a class AB driver, and the peaking amplifier(s) are biased to operate as class C drivers.

In such an embodiment, the carrier amplifier can comprise one or more transistors (e.g., including a driver transistor and a final stage transistor, or just a final stage transistor), and the peaking amplifier can comprise one or more other transistors (e.g., including a driver transistor and a final stage transistor, or just a final stage transistor). Thus, single stage (e.g., single transistor) carrier and peaking amplifiers can be used in some embodiments, and other embodiments can include multiple-stage amplifiers (e.g., in which each amplification path includes a driver amplifier (transistor) and a final-stage amplifier (transistor) coupled in series).

In a typical Doherty implementation, when the input RF signal is at relatively low signal levels, the carrier amplifier operates near its compression point and thus with high efficiency, while the peaking amplifier(s) are not operating. Thus, at relatively low signal levels the Doherty amplifier can provide high efficiency. Then, when higher signal levels occur, the carrier amplifier compresses, and one or more of the peaking amplifier(s) start to operate to “top up” the resulting output signal. Thus, the peaking amplifier(s) provide the ability to achieve high power output during times of high input signal levels. Thus, the carrier and peaking amplifiers of the Doherty amplifier together can provide relatively high power output and high efficiency. Stated another way, Doherty amplifiers thus can combine class AB and class C amplifiers in a way that maintains linearity while providing high power efficiency and can further provide high power output.

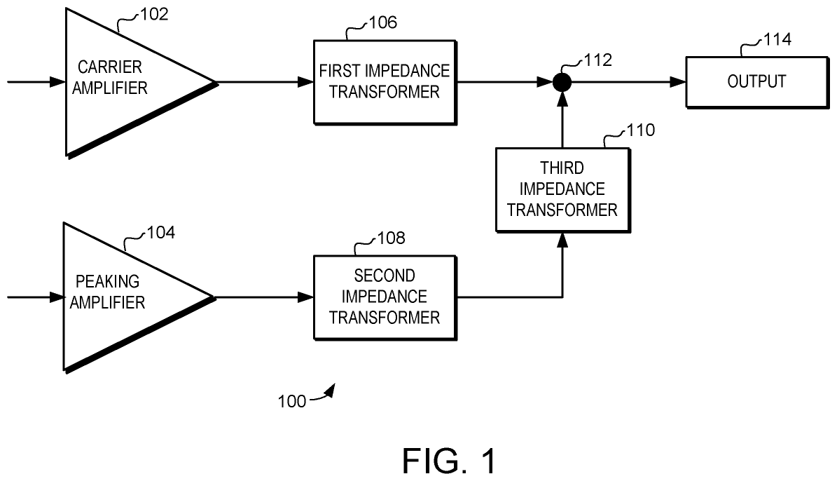

Turning now to FIG. 1, a schematic view of a portion of an exemplary Doherty amplifier 100 in accordance with the embodiments described herein is illustrated. The Doherty amplifier 100 includes a carrier amplifier 102, a peaking amplifier 104, a first impedance transformer 106, a second impedance transformer 108 and a third impedance transformer 110. The carrier amplifier 102 is configured to receive a first RF signal and includes a carrier amplifier output that has a carrier amplifier output impedance. Likewise, the peaking amplifier 104 is configured to receive a second RF signal and includes a peaking amplifier output that has a peaking amplifier output impedance. Not shown in FIG. 1 is the input side of the Doherty amplifier 100, including any signal dividers and input impedances matching elements that may be included in a typical Doherty amplifier.

In some embodiments the Doherty amplifier 100 is a symmetric Doherty amplifier, where the peaking amplifier 104 has equal power capacity to the carrier amplifier 102. As will be described in greater detail below, in other embodiments the Doherty amplifier 100 is an asymmetric Doherty amplifier where the peaking amplifier 104 has a significantly larger power capacity compared to the carrier amplifier 102. Furthermore, in some embodiments multiple peaking amplifiers 104 can be used.

In general, the first impedance transformer 106, second impedance transformer 108 and third impedance transformer 110 provide a signal combiner for the outputs of the carrier amplifier 102 and the peaking amplifier 104. Specifically, the first impedance transformer 106 is coupled to an output of the carrier amplifier 102, the second impedance transformer 108 is coupled to an output of the peaking amplifier 104. The third impedance transformer 110 is coupled between the first impedance transformer 106 and the second impedance transformer 108. The first impedance transformer 106 is configured to transform the carrier amplifier output impedance with a first impedance transformation. Likewise, the second impedance transformer 108 is configured to transform the peaking amplifier output impedance with a second impedance transformation. The third impedance transformer 110 is configured to provide an optimized third impedance transformation and an optimized phase shift.

In this illustrated embodiment the output of the first impedance transformer 106 and the third impedance transformer 110 are combined at a combining node 112, and the combined output is provided to the output 114. It should be noted that the embodiments described herein can be applied to both inverted Doherty and non-inverted Doherty amplifiers. In general, in traditional Doherty configurations the peaking amplifier 104 receives a signal that is phase delayed relative to the signal received by the carrier amplifier 102. In contrast, in inverted Doherty configurations the carrier amplifier 102 receives a signal that is phase delayed relative to the signal received by the peaking amplifier 104. Stated more precisely, in some non-inverted Doherty configurations the signal applied to the carrier amplifier can have a phase difference of 90 degrees relative to the combining node 112, while the signal applied to the peaking amplifier has a phase difference of N*180 degrees (where N can equal 0, 1, 2, etc.) relative to the combining node 112. In inverted Doherty configurations the signal applied to the carrier amplifier can have a phase difference of 270 degrees relative to the combining node 112, while the signal applied to the peaking amplifier has a phase difference of N*180 degrees (where N can equal 0, 1, 2, etc.) relative to the combining node 112.

In both cases the third impedance transformer 110 is between the first impedance transformer 106 and the second impedance transformer 108, and in both cases the use of the third impedance transformer 110 to provide an optimized third impedance transformation and an optimized phase shift can improve Doherty amplifier efficiency.

In general, the optimized phase shift provided by the third impedance transformer 110 presents an open impedance to the combining node 112 between the first impedance transformer 106 and the third impedance transformer 110 during low power operation when the peaking amplifier 104 is off. Furthermore, the optimized impedance provided by the third impedance transformer 110 provides an optimal impedance at the node between the third impedance transformer 110 and the second impedance transformer 108.

When implemented, the third impedance transformer 110 thus provides an optimized phase shift and significantly improved matching quality of the peaking amplifier 104 between the third impedance transformer 110 and the second impedance transformer 108. As will be described in greater detail below, the optimized phase shift provided by the third impedance transformer 110 allows the signals outputted by the carrier amplifier 102 and the peaking amplifier 104 to be combined in phase. Furthermore, the optimized phase shift provided by the third impedance transformer 110 presents an open impedance to the combining node 112 when the peaking amplifier 104 is off that minimizes the impact of the peaking amplifier 104 on the performance of the carrier amplifier 102 when the peaking amplifier 104 is off. Moreover, the optimized phase shift allows the output of the carrier amplifier 102 and the peaking amplifier 104 to be combined in phase when the peaking amplifier 104 is on.

Furthermore, the impedance change provided by the third impedance transformer 110 can improve the efficiency of the peaking amplifier 104 and thus increase the overall efficiency of the Doherty amplifier 100. In particular, this impedance change can improve efficiency during high power operation of the Doherty amplifier 100 when the peaking amplifier 104 is turned on. Furthermore, the impedance change provided by the third impedance transformer 110 can improve the matching quality of the peaking amplifier 104 and thus increase the overall performances of the Doherty amplifier 100. In particular, this impedance change can improve peak power and efficiency during high power operation of the Doherty amplifier 100.

While the third impedance transformer 110 optimizes the output impedance of the peaking amplifier 104, the third impedance transformer 110 does not similarly affect the output impedance seen by the carrier amplifier 102. Thus, the output impedance seen by the carrier amplifier 102 can determined independently of the output impedance seen by the peaking amplifier 104. Stated another way, the impedance transformation provided by the third impedance transformer 110 allows the decoupling of the impedances provided at the carrier output and peaking output such that the optimal impedances can be provided to the outputs of both amplifiers 102, 104 to improve overall power efficiency of the Doherty amplifier 100. For example, this decoupling can allow optimal independent matching for the carrier amplifier 102 and the peaking amplifier 104.

As described above, in some embodiments Doherty amplifier 100 is an asymmetric Doherty amplifier where the peaking amplifier 104 has a significantly larger power capacity compared to the carrier amplifier 102. As non-limiting examples, the peaking amplifier 104 can have a power capacity that is 2, 4, or 8 times larger than the power capacity of the carrier amplifier 102. In such embodiments, the impedance change provided by the third impedance transformer 110 can improve the matching quality of such a relatively large peaking amplifier 104.

Specifically, in these asymmetric Doherty amplifier embodiments the impedance change provided by the third impedance transformer can comprise an increase in impedance. This increase in impedance provided by the third impedance transformer 110 can significantly increase the impedance seen by the high-power peaking amplifier 104, and thus can facilitate improved efficiency in the operation of the larger peaking amplifier 104.

And again, while in these embodiments the third impedance transformer 110 increases the output impedance of the peaking amplifier 104, the third impedance transformer 110 does not similarly increase the output impedance seen by the carrier amplifier 102. Thus, the output impedance seen by the carrier amplifier 102 can again be determined independently of the output impedance seen by the peaking amplifier 104 to allow for optimal independent matching for the carrier amplifier 102 and the peaking amplifier 104.

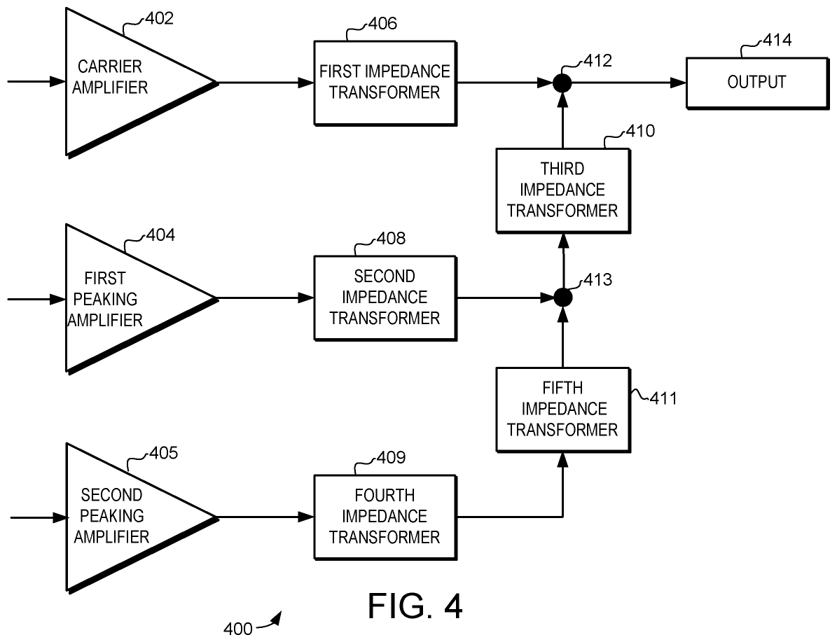

Furthermore, in some embodiments multiple peaking amplifiers 104 can be used. In those cases, multiple third impedance transformers 110 can be used to optimize the impedance seen by each of the multiple peaking amplifiers 104. An example of such an embodiment will be described in greater detail down below with reference to FIG. 4.

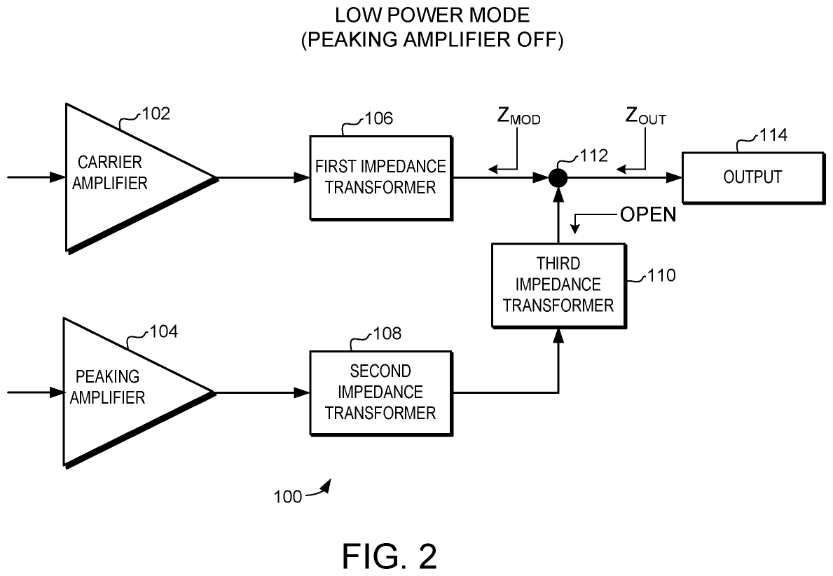

Turning now to FIG. 2, the Doherty amplifier 100 is illustrated with various impedances that occur in low-power operational modes where the peaking amplifier 104 is turned off. In this example, the Doherty amplifier 100 has a system impedance Z_{M}, where the system impedance Z_{M} is typical defined as the optimal impedance to deliver maximum power on the carrier amplifier 102. Likewise, in this example the Doherty amplifier 100 has an output impedance Z_{OUT} defined as the impedance looking toward the combining node 112 from the output 114.

During such a low-power operational mode with the peaking amplifier 104 turned off the impedance looking toward the first impedance transformer 106 from the combining node 112 is defined as Z_{MOD}. In such a Doherty amplifier 100 and with the peaking amplifier 104 turned off, the impedance looking toward the third impedance transformer 110 from the combining node 112 is an open circuit. Thus, in this configuration and with the peaking amplifier 104 turned off these impedance values are:

$${Z}_{OUT} = {Z}_{MOD} = \frac{{Z}_{M}}{r + 1}$$

where r is again the ratio of peaking amplifier 104 power capacity to carrier amplifier 102 power capacity.

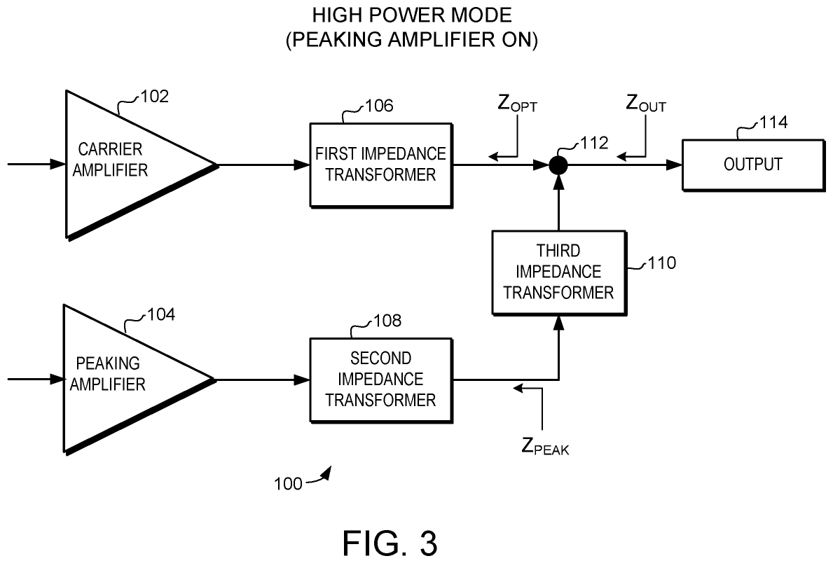

Turning now to FIG. 3, the Doherty amplifier 100 is illustrated with various impedances that occur in high-power operational mode where the peaking amplifier 104 is turned on. In this example, the Doherty amplifier 100 again has a system impedance Z_{M} and an output impedance Z_{OUT}. During such a high-power operational mode the impedance looking toward the first impedance transformer 106 from the combining node 112 is defined as Z_{OPT}. In this configuration, and with the peaking amplifier 104 turned on, these impedance values are as follows:

$${Z}_{OUT} = \frac{{Z}_{M}}{r + 1} \\ {Z}_{OPT} = {Z}_{M}$$

where r is again the ratio of peaking amplifier 104 power capacity to carrier amplifier 102 power capacity.

Also, during such a high-power operational mode the impedance looking toward the second impedance transformer 108 from the third impedance transformer 110 is defined as Z_{PEAK}. Without the presence of the third impedance transformer 110 the impedance Z_{PEAK} is determined exclusively by the system impedance Z_{M}. Specifically, without the presence of the third impedance transformer 110 the “unmodified” value of Z_{PEAK} is:

$${Z}_{PEAK ( UNMODIFIED )} = \frac{{Z}_{M}}{r}$$

where r is again the ratio of peaking amplifier 104 power capacity to carrier amplifier 102 power capacity. Thus, Z_{PEAK} is tied to the system impedance Z_{M} and the ratio r and cannot be independently optimized. As was described above, this can prevent efficient operation of the Doherty amplifier. However, in accordance with the embodiments described herein, the presence of the third impedance transformer 110 allows Z_{PEAK} to be change the impedance to improve the high-power operation of the peaking amplifier 104. Specifically, in some embodiments, the presence of the third impedance transformer 110 allows Z_{PEAK} to be increased or decreased such that such that:

$${Z}_{PEAK ( MODIFIED )} \neq \frac{{Z}_{M}}{r}$$

To accomplish this, the third impedance transformer 110 is configured to provide a third impedance transformation and an optimized phase shift. The optimized phase shift presents an open impedance to the combining node 112 when the peaking amplifier 104 is off that minimizes the impact of the peaking amplifier 104 on the performance of the carrier amplifier 102 when the peaking amplifier 104 is off. Moreover, the optimized phase shift allows the output of the carrier amplifier 102 and the peaking amplifier 104 to be combined in phase when the peaking amplifier 104 is on.

As one example, the optimized phase shift can be implemented to provide a phase shift of 90 degrees when the impedance between the second impedance transformer 108 and the third impedance transformer 110 is exclusively a real impedance. Conversely, the optimized phase shift may be implemented to be higher or lower than 90 degrees when the impedance between the second impedance transformer 108 and the third impedance transformer 110 has a significant imaginary (i.e., reactive) component.

Thus, in one embodiment where the impedance between the second impedance transformer 108 and the third impedance transformer 110 is a real impedance, the third impedance transformer 110 is implemented to provide the phase shift of 90 degrees. In another embodiment where the impedance between the second impedance transformer 108 and the third impedance transformer 110 includes a reactive component and the third impedance transformer is implemented to provide a non 90 degree phase shift. For example, the third impedance transformer can be implemented to provide a phase shift greater than 87 degrees and less than 90 degrees. Alternatively, the third impedance transformer can be implemented to provide a phase shift greater than 90 degrees and less than 93 degrees.

The third impedance transformation provided by the third impedance transformer 110 is configured to improve efficiency during high power operation of the Doherty amplifier 100 when the peaking amplifier 104 is turned on by improving the matching quality of the peaking amplifier 104. This improved matching can provide improved peak power and efficiency during high power operation.

Again, while the third impedance transformer 110 can be used to change Z_{PEAK}, the third impedance transformer 110 does not similarly increase Z_{OPT}. Thus, the output impedance seen by the carrier amplifier 102 can determined independently of the output impedance seen by the peaking amplifier 104. Stated another way, the impedance transformation provided by the third impedance transformer 110 allows the decoupling of the impedances provided at the carrier output and peaking output such that the optimal impedances can be provided to the outputs of both amplifiers 102, 104 to improve overall power efficiency of the Doherty amplifier 100.

In one embodiment, the third impedance transformer 110 is implemented to provide an impedance transformation equal to:

$$\sqrt{\frac{{Z}_{M}}{r} * {Z}_{PEAK}}$$

where Z_{M} is the characteristic impedance of the Doherty amplifier 100, r is ratio of peaking amplifier 104 power capacity to carrier amplifier 102 power capacity, and Z_{PEAK} is the selected peaking amplifier 104 output impedance. In this embodiment, the third impedance transformer 110 provides the impedance at the combining node for correct load modulation between Z_{OPT} and Z_{MOD}.

As described above, in some embodiments Doherty amplifier 100 is an asymmetric Doherty amplifier where the peaking amplifier 104 has a significantly larger power capacity compared to the carrier amplifier 102. In such embodiments, the impedance change provided by the third impedance transformer 110 can improve the matching quality of such a relatively large peaking amplifier 104. Specifically, in these embodiments the presence of the third impedance transformer 110 allows Z_{PEAK} to be change the impedance to improve the high-power operation of the peaking amplifier 104. Specifically, in some embodiments, the presence of the third impedance transformer 110 allows Z_{PEAK} to be increased to for asymmetric Doherty amplifiers where r is greater than 1 such that:

$${Z}_{PEAK ( MODIFIED )} > \frac{{Z}_{M}}{r}$$

Again, while the third impedance transformer 110 can be used to increase Z_{PEAK} in these asymmetric Doherty amplifiers, the third impedance transformer 110 does not similarly increase Z_{OPT}. Thus, the output impedance seen by the smaller carrier amplifier 102 can determined independently of the output impedance seen by the larger peaking amplifier 104. Thus, the third impedance transformer 110 allows the decoupling of the impedances provided at the smaller carrier amplifier 102 output and the larger peaking amplifier 104 output such that the optimal impedances can be provided to the outputs of both.

In one embodiment, the third impedance transformer 110 is implemented to provide an impedance transformation equal to:

$$\sqrt{\frac{{Z}_{M}}{r} * {Z}_{PEAK}}$$

where Z_{M} is the characteristic impedance of the Doherty amplifier 100, r is ratio of peaking amplifier 104 power capacity to carrier amplifier 102 power capacity, and Z_{PEAK} is the selected peaking amplifier 104 output impedance. In this embodiment, the third impedance transformer 110 provides the impedance at the combining node for correct load modulation between Z_{OPT} and Z_{MOD} in such an asymmetric Doherty amplifier 100.

A detailed example of such an asymmetric Doherty amplifier will now be discussed. In this example, the Doherty amplifier is an asymmetric Doherty amplifier with r=2 and a system impedance Z_{M} equal to 10 ohms. Using the equations above, Z_{OPT} is then 10 ohms, while Z_{OUT} and Z_{MOD} are both 3.33 ohms. Without the presence of the third impedance transformer 110, the impedance looking toward the second impedance transformer 108 from the third impedance transformer 110 Z_{PEAK} is unmodified and thus Z_{PEAK}(UNMODIFIED) would equal to 5 ohms. This value of Z_{PEAK} could be not optimized for efficient operation of a relatively large peaking amplifier. However, in accordance with the embodiments described herein, the third impedance transformer 110 is used to increase the value of Z_{PEAK}. For example, to provide a Z_{PEAK}(MODIFIED) value of 30 ohms, the third impedance transformer can be configured to provide an impedance transformation of:

$$\sqrt{\frac{{Z}_{M}}{r} * {Z}_{PEAK}} = \sqrt{\frac{10}{2} * 30} = 12.25 ohms$$

Thus, the third impedance transformer 110 can be implemented to provide an impedance transformation of 12.24 ohms to provide an optimized value of Z_{PEAK} equal to 30 ohms. In such an embodiment the first impedance transformer 106 can be independently optimized to provide the desired carrier amplifier output match, and the second impedance transformer 108 can be independent optimized to provide the desired peaking amplifier output match. For example, the first impedance transformer 106 can be implemented to provide an impedance transformation of 10 ohms such that the carrier amplifier 102 sees an impedance of 10 ohms when the peaking amplifier 104 is on and 30 ohms when the peaking amplifier 104 is off. Likewise, the second impedance transformer 108 can be implemented to provide an impedance transformation of 7.74 ohms such that the peaking amplifier sees an output impedance of 2 ohms.

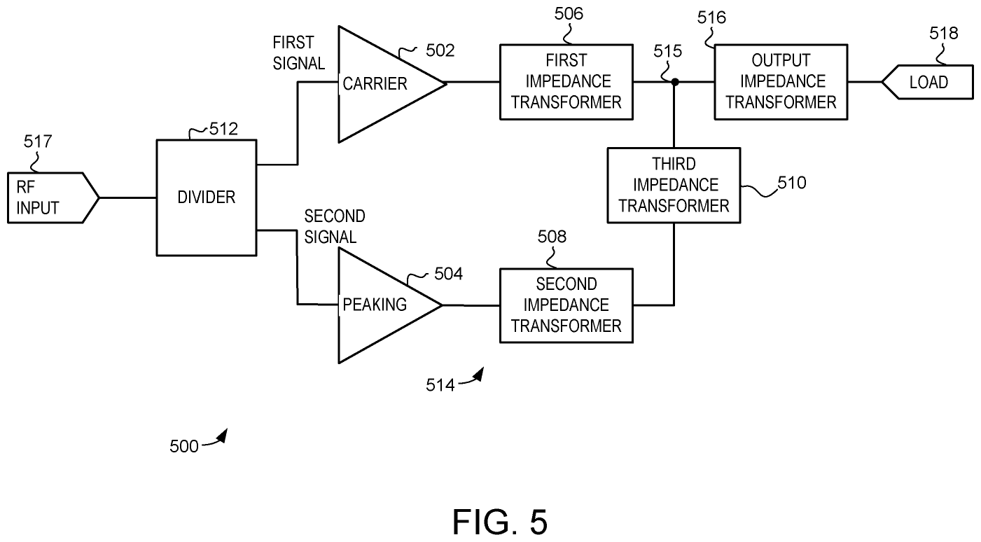

Furthermore, in such an example an output impedance transformer can be coupled to the output 114 to transform the impedance to a desired load impedance. Specifically, the output impedance transform can be implemented to transform Z_{OUT} to a desired load impedance Z_{L}. An example of such an output impedance transformer will be discussed below with reference to FIG. 5.

The first impedance transformer 106 and the second impedance transformer 108 can be implemented with any suitable devices and structure. In one embodiment, the first impedance transformer 106 and the second impedance transformer 108 are both implemented with microstrip impedance transformers. For example, the first impedance transformer 106 and the second impedance transformer 108 can each be implemented with appropriately dimensioned microstrip lines that are designed and implemented to provide the desired impedance matching. As other examples, the first impedance transformer 106 and the second impedance transformer 108 can each be implemented with any suitable combination of impedance (e.g., capacitive and inductive) elements.

Likewise, the third impedance transformer 110 can be implemented with any suitable devices and structure. In one embodiment, the third impedance transformer 110 is implemented with appropriately dimensioned microstrip impedance transformer designed to provide an optimal phase shift and impedance transformation. As other examples, the third impedance transformer 110 can be implemented with any suitable combination of impedance (e.g., capacitive and inductive) elements

In such an embodiment the additional impedance matching can be provided with other elements inside the device package. For example, other elements can be provided to compensate for intrinsic impedances, including intrinsic source drain capacitances (CDs).

It should be noted that Doherty amplifier 100 is a simplified representation of a portion of an amplifier, and in a more typical implementation the Doherty amplifier 100 would include additional features not illustrated in FIG. 1, 2 or 3. For example, the amplifier 100 could include a variety of bias circuits.

As described above, in some embodiments multiple peaking amplifiers 104 can be used. And in those, multiple third impedance transformers 110 can be used to increase the impedance seen by each of the multiple peaking amplifiers 104.

Turning now to FIG. 4, a schematic view of a portion of a second exemplary Doherty amplifier 400 in accordance with the embodiments described herein is illustrated. In general, the Doherty amplifier 400 is similar to Doherty amplifier 100 discussed above, but includes multiple peaking amplifiers and additional impedance transformers. Specifically, the Doherty amplifier 400 includes a carrier amplifier 402, a first peaking amplifier 404, a second peaking amplifier 405, a first impedance transformer 406, a second impedance transformer 408, a third impedance transformer 410, a fourth impedance transformer 409 and a fifth impedance transformer 411. The carrier amplifier 402 is configured to receive a first RF signal and includes a carrier amplifier output that has a carrier amplifier output impedance. Likewise, the first peaking amplifier 404 is configured to receive a second RF signal and includes a first peaking amplifier output that has a first peaking amplifier output impedance. Finally, the second peaking amplifier 405 is configured to receive a third RF signal and includes a second peaking amplifier output that has a second peaking amplifier output impedance.

In general, the first impedance transformer 406, second impedance transformer 408, third impedance transformer 410, fourth impedance transformer 409, and fifth impedance transformer 411 provide signal combiners for the outputs of the carrier amplifier 402, the first peaking amplifier 404, and the second peaking amplifier 105. Specifically, the first impedance transformer 406 is coupled to an output of the carrier amplifier 402, the second impedance transformer 408 is coupled to an output of the first peaking amplifier 404, and the fourth impedance transformer 409 is coupled to an output of the second peaking amplifier 405.

The third impedance transformer 410 is coupled between the first impedance transformer 406 and the second impedance transformer 408. The first impedance transformer 406 is configured to transform the carrier amplifier output impedance with a first impedance transformation. Likewise, the second impedance transformer 408 is configured to transform the first peaking amplifier output impedance with a second impedance transformation. The third impedance transformer 410 is configured to provide a third impedance transformation and a phase shift.

The fifth impedance transformer 411 is coupled between the fourth impedance transformer 409 and the second impedance transformer 408. The fourth impedance transformer 409 is configured to transform the second peaking amplifier output impedance with a fourth impedance transformation. Likewise, the fifth impedance transformer 411 is configured to provide a fifth impedance transformation and a phase shift.

In this illustrated embodiment, the output of the fifth impedance transformer 411 and the output of the second impedance transformer 408 are combined at a combining node 413. Likewise, the output of the third impedance transformer 410 and the first impedance transformer 406 are combined at a combining node 412, and the combined output is provided to the output 414.

In accordance with the embodiments described herein, the third impedance transformer 410 is configured to both provide an optimized phase shift and an impedance change to improve the matching quality of first peaking amplifier 404 and the second peaking amplifier 405 to increase the overall performances of the Doherty amplifier 400. Likewise, the fifth impedance transformer 411 is configured to both provide an optimized phase shift and an impedance change to improve the matching quality of second peaking amplifier 405.

In particular, the optimized phase shift provided by the third impedance transformer 410 and the optimized phase shift provided by the fifth impedance transformer 411 are selected to cause the peaking amplifiers 404 and 405 to present an open circuit at the combining node 412 when the peaking amplifiers 404 and 405 are off. When so configured, the optimized phase shift provided by the third impedance transformer 410 and the fifth impedance transformer 411 minimizes the impact of peaking amplifiers 404 and 405 on carrier amplifier performances when peaking amplifiers 404 and 405 are off during low power operation.

Furthermore, the impedance change provided by third impedance transformer 410 and the fifth impedance transformer 411 can improve peak power and efficiency during high power operation of the Doherty amplifier 400. Finally, the third impedance transformer 410 and the fifth impedance transformer 411 allows the outputs of carrier amplifier 402 and peak amplifiers 404, 405 to be combined in phase when peak amplifiers are on during high power operation.

In this embodiment, the fourth impedance transformer 409 and fifth impedance transformer 411 provide a second signal combiner. The fourth impedance transformer 409 is coupled to the second peaking amplifier output and configured to transform the second peaking amplifier output impedance with a fourth impedance transformation. The fifth impedance transformer 411 is coupled between the fourth impedance transformer 409 and the third impedance transformer 410, and the fifth impedance transformer 411 is configured to provide a fifth impedance transformation and a second optimized phase shift. In such an embodiment the fifth impedance transformation can be equal to:

$$\sqrt{\frac{{Z}_{M}}{r 2} * {Z}_{PEAK 2}}$$

where Z_{M} is a characteristic impedance of the Doherty amplifier 400, r2 is ratio of second peaking amplifier 405 power capacity to carrier amplifier 402 power capacity, and Z_{PEAK2} is a selected second peaking amplifier output impedance. In this embodiment, the fifth impedance transformer 411 provides needed impedance at the combining node 413 that results in the correct load modulation between Z_{OUT} and Z_{MOD}.

Turning now to FIG. 5, a circuit diagram representing a portion of an exemplary Doherty amplifier 500 is illustrated. In this illustrated embodiment, the amplifier 500 is a Doherty amplifier that receives an RF input signal at the RF input 517 and drives an amplified signal to a load output 518. The amplifier 500 includes a carrier amplifier 502, a peaking amplifier 504, a divider 512, a combiner 514, and an output impedance transformer 516. In accordance with the embodiments described herein, the combiner 514 includes a first impedance transformer 506, a second impedance transformer 508, and a third impedance transformer 510.

In a typical embodiment, the divider 512 receives an RF signal and generates two output signals that are out of phase with each other (e.g., 90 or 180 degree out of phase). These two outputs correspond to the first signal and second signal that are applied to the carrier amplifier 502 and peaking amplifier 504 respectively. The two outputs can be in the form of equal-power or unequal-power signals. The phase difference can be provided by a phase delay element that applies a phase shift of a selected amount (e.g., 90 degrees) to the second signal before outputting the second signal to the peaking amplifier 504. The difference in phase allows the output of the peaking amplifier 504 to be in step with the carrier amplifier 502 output when combined at the combining node 515.

The amplifier 500 receives and amplifies the first signal and the phase delayed second signal, combines the amplified first and second signals in phase, and drives the combined signal to a load output 518. The carrier amplifier 502 includes one or more carrier transistors, and the peaking amplifier 504 includes one or more peaking transistors, and the outputs of the carrier and peaking transistors are coupled to the combiner 514.

In a typical embodiment, the carrier amplifier 502 and peaking amplifier 504 would be implemented with suitable RF-capable transistors with relatively high power capability. For example, the carrier amplifier 502 and peaking amplifier 504 can be implemented with a variety of different types of transistors, including field effect transistors (FETs) and bipolar junction transistors (BJTs), to give two non-limiting examples. For example, the carrier amplifier 502 and peaking amplifier 504 can be implemented with III-V type transistors (e.g., Gallium Nitride (GaN) transistors), silicon-based transistors (e.g., LDMOS FETs), or other types of transistors. In one specific embodiment, the carrier amplifier 502 and peaking amplifier 504 comprises a gallium nitride (GaN) field-effect transistor (FET). As more specific examples, various III-V field effect transistors may be used (e.g., a high electron mobility transistor (HEMT)), such as a GaN FET (or another type of III-V transistor, including a gallium arsenide (GaAs) FET, a gallium phosphide (GaP) FET, an indium phosphide (InP) FET, or an indium antimonide (InSb) FET). In other examples the carrier amplifier 502 and peaking amplifier 504 may be implemented with a III-V FET or with a silicon-based FET (e.g., a laterally-diffused metal oxide semiconductor (LDMOS) FET).

In a typical Doherty implementation, the carrier amplifier 502 is biased to operate as a class AB amplifier and is used to drive the main body of the output signal. Conversely, the peaking amplifier 504 is biased to operate as a class C amplifier and is used to drive the peaks of the output signal. This use of the two amplifiers 502 and 504 as class AB and class C amplifiers with outputs that are combined together can provide both relatively high power output and high efficiency.

Again, the combiner 514 includes the first impedance transformer 506, the second impedance transformer 508, and the third impedance transformer 510. This combiner 514 serves to the combine the outputs of the carrier amplifier 502 and peaking amplifier 504 such that the combined output can be delivered to the load output 518. The combiner 514 also provides an impedance inversion between the outputs of the carrier amplifier 502 and the peaking amplifier 504. During operation, this impedance inversion effectively changes the impedance seen by the carrier amplifier 502 to provide an optimal load to the carrier amplifier 502 at and around the operational frequency. The combiner 514 also provides a phase shift (e.g., 180 degree) to the output of the peaking amplifier 504 and thus facilitates the in-phase combining of that output with the output of the carrier amplifier 502.

In accordance with the embodiments described herein, the combiner 514 includes the first impedance transformer 506, the second impedance transformer 508, and the third impedance transformer 510. In general, the first impedance transformer 506 and the second impedance transformer 508 are configured to transform the impedance at the output of the carrier amplifier 502 and peaking amplifier 504 to one acceptable for the load. For example, the first impedance transformer 506 and the second impedance transformer 508 can be impedance increasing transformers that increase the final output impedance of the amplifiers closer to a desired final level. Stated another way, the impedance transformation provided by the third impedance transformer 510 facilitates a decoupling of the impedances provided at the carrier amplifier 502 output and peaking amplifier 504 output such that the optimal impedances can be provided to the outputs of both amplifiers to improve overall power efficiency of the Doherty amplifier 500.

The third impedance transformer 110 is again configured to both provide an optimized phase shift and a change in the impedance between the third impedance transformer 110 and the second impedance transformer 108. The optimized phase shift provided by the third impedance transformer 510 allows the signals outputted by the carrier amplifier 502 and the peaking amplifier 504 to be combined in phase. Furthermore, the change in impedance provided by the third impedance transformer 510 can improve the efficiency of the peaking amplifier 504 and thus increase the overall efficiency of the Doherty amplifier 100.

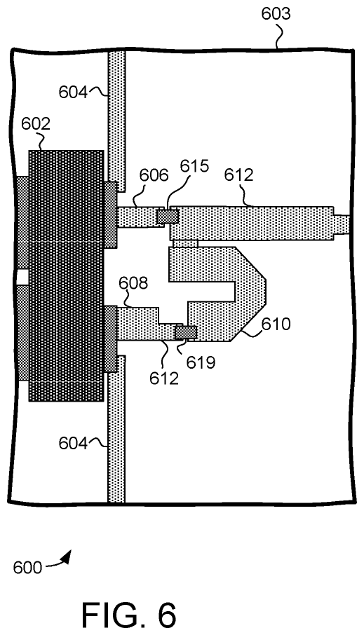

Turning now to FIG. 6, a top view of a portion of a Doherty amplifier 600 is illustrated. The illustrated portion of a Doherty amplifier 600 includes packaged transistor device 602 mounted to a printed circuit board 603. In this embodiment the packaged transistor device 602 includes two encased transistors to implement a carrier and peaking amplifier, two input leads (on the left side of the device 602), and two output leads (on the right side of the device 602). Each encased transistor has its own input (i.e., the two encased transistors are implemented in parallel with each other, each connected between a different input/output lead pair). The printed circuit board 603 includes a plurality of conductive traces, including two bias line traces 604, a first impedance transformer trace 606, a second impedance transformer trace 608, a third impedance transformer trace 610, and an output impedance transformer trace 612. For example, the traces 604, 606, 608, 610, and 612 may be implemented as patterned portions of a conductive layer on a top surface of the printed circuit board 603. Additionally, such traces by be connected together using other elements such as solder connects or other pattered features. Also provided are DC blocking capacitors 615 and 617, where the DC blocking capacitor 615 couples the trace 606 to the trace 612, and the DC blocking capacitor 619 couples the trace 608 to the trace 610.

The bias lines traces 604 are implemented to provide bias voltages to the outputs of the transistors. The impedance transformers traces 606, 608 and 610 together provide a combiner for the Doherty amplifier 600. Specifically, the first impedance transformer trace 606 is coupled to a package output lead on the packaged transistor device 602 corresponding to the carrier amplifier. The first impedance transformer trace 606, in combination with other conductive structures (e.g., wirebonds inside the packaged transistor device 602) thus provides an electrical connection to the output (e.g., the drain terminal) of a corresponding transistor for the carrier amplifier in the packaged transistor device 602. Likewise, the second impedance transformer trace 608 is coupled to a package output lead on the packaged transistor device 602 corresponding to the peaking amplifier. The second impedance transformer trace 608, in combination with other conductive structures (e.g., wirebonds inside the packaged transistor device 602) thus provides an electrical connection to the output (e.g., the drain terminal) of a corresponding transistor for the peaking amplifier in the packaged transistor device 602. The third impedance transformer trace 610 combines the outputs of the two transistors (or more specifically the outputs of the impedance transformer traces 606 and 608) and provides a phase delay to the output of the peaking amplifier. The output transformer trace 612 provides a connection between the combined output to the Doherty amplifier 600 and the load.

In general, the parameters of the various traces are used to provide the desired phase shifts and/or impedance transformations of the impedance transformers traces 606, 608 and 610. For example, the length of impedance transformers traces 606, 608 and 610 determines the amount of phase delay in each trace. For example, to provide a 90 degree phase shift the impedance transformers trace 610 can be implemented to have a length equal to one-quarter wavelength of the expected operational signal. Likewise, the width of the impedance transformers traces 606, 608 and 610 determines the amount impedance transformation by each trace.

Specifically, in one embodiment the first impedance transformer trace 606, second impedance transformer trace 608, and third impedance transformer trace 610 can each be implemented with a microstrip line having a length and width selected to provide a desired impedance transformation. In some embodiments the first impedance transformer trace 606, second impedance transformer trace 608 and third impedance transformer trace 610 can each be implemented with a microstrip line with a length to provide a quarter-wave phase shift for the desired operational frequency, and thus implement a quarter-wave impedance transformer. In other embodiments, portions of the quarter-wave phase shifts are instead provided inside the packaged transistor device 602. In these embodiments the first impedance transformer trace 606 and the second impedance transformer trace 608 would have a shorter length and not provide the full quarter-wave phase shift.

Again, as described above, the first impedance transformer trace 606 and the second impedance transformer trace 608 are configured to transform the impedance at the output of the carrier amplifier and peaking amplifier respectfully. The third impedance transformer trace 610 is between the first impedance transformer trace 606 and the second impedance transformer trace 608.

In accordance with the embodiments described herein, the third impedance transformer trace 610 is configured to both provide an optimized phase shift and change in the impedance between the third impedance transformer trace 610 and the second impedance transformer trace 608. The change in impedance provided by the third impedance transformer trace 610 can improve the matching quality of the peaking amplifier in the packaged transistor device 602 and thus increase the overall performances of the Doherty amplifier 600. In particular, this change in impedance can improve efficiency during high power operation of the Doherty amplifier 600 when the peaking amplifier is turned on. And as described above this is particularly applicable to asymmetric Doherty amplifiers where the peaking amplifier has a significantly larger power capacity compared to the carrier amplifier. In such embodiments the change in impedance provided by the third impedance transformer trace 610 can comprise an increase in impedance by the high-power peaking amplifier, and thus can facilitate improved efficiency in the operation of the larger peaking amplifier.

Finally, the output impedance transformer trace 612 is coupled to first impedance transformer trace 606 and the third impedance transformer trace 610 at the combining node. The output impedance transformer trace 612 transforms the impedance to desired load impedance (e.g., Z_{L}).

It should be noted that the amplifier 600 is just one example implementation, and that other implementations are possible. For example, in some cases one or more additional elements of the Doherty amplifier 600 can be packaged with the transistors in the packaged transistor device 602. Furthermore, one or more of the impedance transformers can be implemented with other devices and structures in place of or in addition to the traces 606, 608 and 610. For example, in some embodiments one or more of the impedance transforms can be implemented instead with discrete passive devices or packaged impedance transformers.

In one embodiment a Doherty power amplifier is provided, comprising: a carrier amplifier, the carrier amplifier including a carrier amplifier output having a carrier amplifier output impedance, the carrier amplifier configured to receive a first radio frequency (RF) signal; a peaking amplifier, the peaking amplifier including a peaking amplifier output having a peaking amplifier output impedance, the peaking amplifier configured to receive a second RF signal; and a combiner, the combiner coupled to the carrier amplifier output and the peaking amplifier output, the combiner including: a first impedance transformer, the first impedance transformer coupled to the carrier amplifier output and configured to transform the carrier amplifier output impedance with a first impedance transformation; a second impedance transformer, the second impedance transformer coupled to the peaking amplifier output and configured to transform the peaking amplifier output impedance with a second impedance transformation; and a third impedance transformer, the third impedance transformer coupled between the first impedance transformer and the second impedance transformer, the third impedance transformer configured to provide a third impedance transformation and a phase shift, the third impedance transformation being an impedance transformation between a characteristic impedance of the Doherty amplifier a selected peaking amplifier output impedance.

In another embodiment, an asymmetric Doherty power amplifier is provided, comprising: a signal divider, the signal divider coupled to a radio frequency (RF) input and configured to generate a first RF signal and a second RF signal, wherein the second RF signal has quarter-wave phase difference with the first RF signal; a carrier amplifier, the carrier amplifier including a carrier amplifier output having a carrier amplifier output impedance, the carrier amplifier configured to receive the first RF signal, and wherein the carrier has a power capacity; a peaking amplifier, the peaking amplifier including a peaking amplifier output having a peaking amplifier output impedance, the peaking amplifier configured to receive the second RF signal, and wherein the peaking amplifier has a power capacity at least twice the power capacity of the peaking amplifier; and a combiner, the combiner coupled to the carrier amplifier output and the peaking amplifier output, the combiner including: a first impedance transformer, the first impedance transformer comprising a first microstrip line coupled a carrier amplifier output and configured to transform the carrier amplifier output impedance with a first impedance transformation; a second impedance transformer, the second impedance transformer comprising a second microstrip line coupled to the peaking amplifier output and configured to transform the peaking amplifier output impedance with a second impedance transformation; and a third impedance transformer, the third impedance transformer comprising a third microstrip line coupled to between the first impedance transformer and the second impedance transformer and configured to configured to provide a third impedance transformation and a phase shift, the third impedance transformation equal to:

$$\sqrt{\frac{{Z}_{M}}{r} * {Z}_{PEAK}}$$

where Z_{M} is a characteristic impedance of the Doherty amplifier, r is ratio of peaking amplifier power capacity to carrier amplifier power capacity, and Z_{PEAK} is a selected peaking amplifier output impedance.

It should be noted that the term “package”, “package device”, or “packaged transistor device”, as used herein means a collection of structural components (e.g., including a flange or other package substrate) to which the primary electrical components (e.g., input and output leads, transistor dies, IPD dies, and various electrical interconnections) are coupled and/or encased. The package, package device, or packaged transistor device is thus a distinct device that may be mounted to a printed circuit board or other substrate that includes other devices and portions of a circuit. As specific examples, the package, package device, or packaged transistor device can comprise an air cavity or over-molded package having a suitable package substrate, input lead(s), and output lead(s). In addition, the package, packaged device, or packaged transistor device could be implemented using other packaging configurations than those shown in the figures, such as but not limited to no-leads packages (e.g., quad flat no-leads, QFN), or other package types.

The preceding detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or the following detailed description.

Furthermore the connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first”, “second” and other such numerical terms referring to structures do not imply a sequence or order unless clearly indicated by the context.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematics shown in the figures depict several exemplary arrangements of elements, additional intervening elements, devices, features, or components may be present in other embodiments of the depicted subject matter.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A Doherty power amplifier comprising:
a carrier amplifier, the carrier amplifier including a carrier amplifier output having a carrier amplifier output impedance, the carrier amplifier configured to receive a first radio frequency (RF) signal;
a peaking amplifier, the peaking amplifier including a peaking amplifier output having a peaking amplifier output impedance, the peaking amplifier configured to receive a second RF signal; and
a combiner, the combiner coupled to the carrier amplifier output and the peaking amplifier output, the combiner including:
a first impedance transformer, the first impedance transformer coupled to the carrier amplifier output and configured to transform the carrier amplifier output impedance with a first impedance transformation;
a second impedance transformer, the second impedance transformer coupled to the peaking amplifier output and configured to transform the peaking amplifier output impedance with a second impedance transformation; and
a third impedance transformer, the third impedance transformer coupled between the first impedance transformer and the second impedance transformer, the third impedance transformer configured to provide a third impedance transformation and a phase shift, the third impedance transformation being an impedance transformation between a characteristic impedance of the Doherty amplifier a selected peaking amplifier output impedance.

2. The Doherty power amplifier of claim 1, wherein the third impedance transformer is implemented with a quarter-wavelength microstrip line and wherein the third impedance transformation is equal to:
$$\sqrt{\frac{{Z}_{M}}{r} * {Z}_{PEAK}}$$
where Z_{M} is the characteristic impedance of the Doherty amplifier, r is ratio of peaking amplifier power capacity to carrier amplifier power capacity, and Z_{PEAK} is the selected peaking amplifier output impedance.

3. The Doherty power amplifier of claim 1, wherein the third impedance transformer is implemented to provide the phase shift such that an open impedance is presented between the first impedance transformer and the third impedance transformer when the peaking amplifier is off.

4. The Doherty power amplifier of claim 1, wherein an impedance between the second impedance transformer and the third impedance transformer is a real impedance and the third impedance transformer is implemented such that the phase shift is 90 degrees.

5. The Doherty power amplifier of claim 1, wherein an impedance between the second impedance transformer and the third impedance transformer includes a reactive component and the third impedance transformer is implemented such that the phase shift is not 90 degrees.

6. The Doherty power amplifier of claim 1, wherein the peaking amplifier has a larger power capacity than the carrier amplifier such that the Doherty amplifier is an asymmetric Doherty amplifier.

7. The Doherty power amplifier of claim 6, wherein the third impedance transformation provides an increase in impedance the impedance between the third impedance transformer and the second impedance transformer.

8. The Doherty power amplifier of claim 1, wherein the peaking amplifier has an equal power capacity to the carrier amplifier such that the Doherty amplifier is an symmetric Doherty amplifier.

9. The Doherty power amplifier of claim 1, wherein the first impedance transformer and the second impedance transformer comprise quarter-wave transformers.

10. The Doherty power amplifier of claim 1, wherein the first impedance transformer comprises a first microstrip line, and wherein the second impedance transformer comprises a second microstrip line, and wherein the third impedance transformer comprises a third microstrip line configured to provide a change in the impedance between the third impedance transformer and the second impedance transformer.

11. The Doherty power amplifier of claim 1, wherein the Doherty power amplifier is an inverted Doherty amplifier.

12. The Doherty power amplifier of claim 1, wherein Z_{M} is a characteristic impedance of the Doherty power amplifier, and wherein an impedance at the output of the first impedance transformer is equal to Z_{M} when the peaking amplifier is on.

13. The Doherty power amplifier of claim 1, wherein Z_{M} is a characteristic impedance of the Doherty power amplifier, and wherein an impedance at a combining node of the first impedance and the third impedance is equal to Z_{M}/(r+1) where when the peaking amplifier is on, where r is a ratio of peaking amplifier power capacity to carrier amplifier power capacity.

14. The Doherty power amplifier of claim 1 further comprising:
a second peaking amplifier, second the peaking amplifier including a second peaking amplifier output having a second peaking amplifier output impedance, the second peaking amplifier configured to receive a third RF signal; and
a second combiner, the second combiner coupled to the peaking amplifier output and the second peaking amplifier output, the second combiner including:
a fourth impedance transformer, the fourth impedance transformer coupled to the second peaking amplifier output and configured to transform the second peaking amplifier output impedance with a fourth impedance transformation; and
a fifth impedance transformer, the fifth impedance transformer coupled between the fourth impedance transformer and the third impedance transformer, the fifth impedance transformer configured to provide a fifth impedance transformation and a second phase shift, the fifth impedance transformation equal to:
$$\sqrt{\frac{{Z}_{M}}{r 2} * {Z}_{PEAK 2}}$$
where Z_{M} is a characteristic impedance of the Doherty amplifier, r2 is ratio of second peaking amplifier power capacity to carrier amplifier power capacity, and Z_{PEAK2} is a selected second peaking amplifier output impedance.

15. An asymmetric Doherty power amplifier comprising:
a signal divider, the signal divider coupled to a radio frequency (RF) input and configured to generate a first RF signal and a second RF signal, wherein the second RF signal has quarter-wave phase difference with the first RF signal;
a carrier amplifier, the carrier amplifier including a carrier amplifier output having a carrier amplifier output impedance, the carrier amplifier configured to receive the first RF signal, and wherein the carrier has a power capacity;
a peaking amplifier, the peaking amplifier including a peaking amplifier output having a peaking amplifier output impedance, the peaking amplifier configured to receive the second RF signal, and wherein the peaking amplifier has a power capacity at least twice the power capacity of the peaking amplifier; and
a combiner, the combiner coupled to the carrier amplifier output and the peaking amplifier output, the combiner including:
a first impedance transformer, the first impedance transformer comprising a first microstrip line coupled a carrier amplifier output and configured to transform the carrier amplifier output impedance with a first impedance transformation;
a second impedance transformer, the second impedance transformer comprising a second microstrip line coupled to the peaking amplifier output and configured to transform the peaking amplifier output impedance with a second impedance transformation; and
a third impedance transformer, the third impedance transformer comprising a third microstrip line coupled to between the first impedance transformer and the second impedance transformer and configured to configured to provide a third impedance transformation and a phase shift, the third impedance transformation equal to:
$$\sqrt{\frac{{Z}_{M}}{r} * {Z}_{PEAK}}$$
where Z_{M} is a characteristic impedance of the Doherty amplifier, r is ratio of peaking amplifier power capacity to carrier amplifier power capacity, and Z_{PEAK} is a selected peaking amplifier output impedance.

16. The asymmetric Doherty power amplifier of claim 15, wherein the third impedance transformer is implemented to provide the phase shift such that an open impedance is presented between the first impedance transformer and the third impedance transformer when the peaking amplifier is off.

17. The asymmetric Doherty power amplifier of claim 15, wherein an impedance between the second impedance transformer and the third impedance transformer is a real impedance and the third impedance transformer is implemented such that the phase shift is 90 degrees.

18. The asymmetric Doherty power amplifier of claim 15, wherein an impedance between the second impedance transformer and the third impedance transformer includes a reactive component and the third impedance transformer is implemented such that the phase shift is not 90 degrees.

19. The asymmetric Doherty power amplifier of claim 15 further comprising:
a second peaking amplifier, second the peaking amplifier including a second peaking amplifier output having a second peaking amplifier output impedance, the second peaking amplifier configured to receive a third RF signal; and
a second combiner, the second combiner coupled to the peaking amplifier output and the second peaking amplifier output, the second combiner including:
a fourth impedance transformer, the fourth impedance transformer coupled to the second peaking amplifier output and configured to transform the second peaking amplifier output impedance with a fourth impedance transformation; and
a fifth impedance transformer, the fifth impedance transformer coupled between the fourth impedance transformer and the third impedance transformer, the fifth impedance transformer configured to provide a fifth impedance transformation and a second phase shift, the fifth impedance transformation equal to:
$$\sqrt{\frac{{Z}_{M}}{r 2} * {Z}_{PEAK 2}}$$
where r2 is ratio of second peaking amplifier power capacity to carrier amplifier power capacity and Z_{PEAK2} is a selected second peaking amplifier output impedance.

20. The asymmetric Doherty power amplifier of claim 19, wherein the fourth impedance transformer comprises a fourth microstrip line, and wherein the fifth impedance transformer comprises a fifth microstrip line.
